(19) United States
(12) Patent Application Publication
(10) Pub. No.: US 2012/0048379 A1
(43) Pub. Date: Mar. 1, 2012

(54) INTELLIGENT THIN FILM SOLAR CELL HAVING TEMPERATURE DEPENDENT INFRARED LIGHT TRANSMITTANCE CAPABILITY

(75) Inventors: YEE SHYI CHANG, TAIPEI (TW); CHANG CHI MEI, TAIPEI (TW); CHI-JEN LIU, TAIPEI (TW)

(73) Assignee: AN CHING NEW ENERGY MACHINERY & EQUIPMENT CO., LTD, Taipei (TW)

(21) Appl. No.: 13/017,515

(22) Filed: Jan. 31, 2011

(30) Foreign Application Priority Data
Aug. 25, 2010 (TW) 99128500

(51) Int. Cl. H01L 31/02

(52) U.S. Cl. 136/265; 136/252

(57) ABSTRACT

An intelligent thin film solar cell having temperature dependent infrared light transmittance capability, comprising: a transparent substrate, an upper electrode layer, a photovoltaic layer, a lower electrode layer, a temperature dependent optical layer, and an ultra-thin conductive layer. Said upper electrode layer is disposed on said transparent substrate, said photovoltaic layer is disposed on said upper electrode layer, and said lower electrode layer is disposed on said photovoltaic layer. Said temperature dependent optical layer is disposed between said photovoltaic layer and said lower electrode layer, and its transmittance to infrared light is dependent on variations of temperature. When temperature of said temperature dependent optical layer increases to a specific range, transmittance of said temperature dependent optical layer to said infrared light is reduced. Said ultra-thin conductive layer is disposed on said lower electrode layer, and reflects said infrared light transmitted through said temperature dependent optical layer.

### BACKGROUND OF THE INVENTION

1. Field of the Invention

The present invention relates to a solar cell, and in particular to a thin film solar cell capable of regulating transmittance of infrared light based on the temperature, and also the ratio of infrared light passing through the thin film solar cell based on the design requirements.

2. The Prior Arts

Along with the global concern about environment protection, and worldwide acceptance and implementation of the concept of “energy conservation and carbon reduction”, therefore, the development and utilization of regenerated energy resources has been the keypoint of development for various countries of the world. Among the regenerated energy resources, solar energy and solar cell capable of converting sunlight into electrical energy are of the most promising energy industry, since sunlight is available all over the world, and it would not create pollution to the Earth like other energy resources (such as nuclear energy, petrochemical energy).

In case that the solar cell is provided with a large light irradiating area, then it can produce relatively large amount of electrical energy for use by various devices. Therefore, quite a lot of manufacturers hope to combine the concept of “green energy building” with the solar cell, namely, putting solar cell in a building, where it is most exposed and irradiated by sunlight, as such, the energy generated by solar cell can be used to compensate for the electrical energy consumed by the building.

Presently, the crucial problem of solar cell development lies in raising its photoelectric conversion efficiency, such that the capability of increasing photoelectric conversion efficiency of the solar cell means raising the competitiveness of the solar cell product. In addition, since the material required for making solar cell is readily available, so it has wide range of application and that catches the attention of various industries.

However, presently, the photoelectric conversion efficiency of a solar cell is still not perfect, and it has much room for improvement.

### SUMMARY OF THE INVENTION

In view of the problems and shortcomings of the prior art, the present invention provides an intelligent thin film solar cell having temperature dependent infrared light transmittance capability, that is capable of regulating automatically the transmittance/reflectance of infrared light based on ambient temperature. Also, an ultra-thin conductive layer is utilized for regulating the transmittance/reflectance as required.

In order to achieve the above-mentioned objective, the present invention provide an intelligent thin film solar cell having temperature dependent infrared light transmittance capability, comprising: a transparent substrate, an upper electrode layer, a photovoltaic layer, a lower electrode layer, a temperature dependent optical layer, and an ultra-thin conductive layer. In the structure mentioned above, the upper electrode layer is provided on the transparent substrate, the photovoltaic layer is provided on the upper electrode layer, the lower electrode layer is provided on the photovoltaic layer, and the temperature dependent optical layer is disposed between the photovoltaic layer and the lower electrode layer, the transmittance of which for infrared light can be varied depending on temperature. When the temperature of the temperature dependent optical layer increases to a specific range, the transmittance of the temperature dependent optical layer for the infrared light will be lowered. An ultra-thin conductive layer is disposed on the lower electrode layer, and it reflects the infrared light passing through this temperature dependent optical layer.

In an embodiment of the present invention, the thickness of the ultra-thin conductive layer is equal to or greater than 2 nm, and is equal or less than 20 nm.

In another embodiment of the present invention, the ultra-thin conductive layer is made of transition metals, such as Ni, Ag, or Al.

In a yet another embodiment of the present invention, the temperature dependent optical layer is made of vanadium dioxide or compound of vanadium and oxygen. In addition, the temperature dependent optical layer can be doped with element of Ti, Ag, or Cu, etc.

In a further embodiment of the present invention, when temperature increases to above 30° C., the transmittance of the temperature dependent optical layer for infrared light will be lowered; and when temperature drops to below 20° C., the transmittance of the temperature dependent optical layer for infrared light will be increased.

In a yet another embodiment of the present invention, along with the increase of temperature, the transmittance of the temperature dependent optical layer for the infrared light will be reduced.

In a further embodiment of the present invention, the photovoltaic layer includes an N-type semiconductor layer and a P-type semiconductor layer, disposed sequentially between an upper electrode layer and a lower electrode layer.

According to the above descriptions, when sunlight enters into a thin film solar cell from a side of transparent substrate, the temperature dependent optical layer disposed between the photovoltaic layer and the lower electrode layer will regulate the transmittance of sunlight of the infrared frequency section passing through the thin film solar cell as based on the present temperature. In addition, in the present embodiment, an ultra-thin conductive layer regulates further the ratio of infrared light passing through the thin film solar cell, so that lighting and temperature of a building can be controlled based on the transmittance of infrared light as specified by the designer, so as to reduce the utilization rate of air conditioner.

Moreover, in addition to being applicable to window or roof of a building in regulating the room temperature, the intelligent thin film solar cell having temperature dependent infrared light transmittance capability of the present invention can also be applicable to a plant or flower cultivating industry requiring much more green light or mixture of blue light and green light, so as to maintain a decent room temperature advantageous for cultivating flowers and plants. In order words, the intelligent thin film solar cell having temperature dependent infrared light transmittance capability of the present invention is able to make great contributions to various Industries.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a cross section view of an intelligent thin film solar cell having temperature dependent infrared light transmittance capability according to an embodiment of the present invention; and

FIG. 2 is a schematic diagram showing the infrared light transmittance of temperature dependent optical layer according to an embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

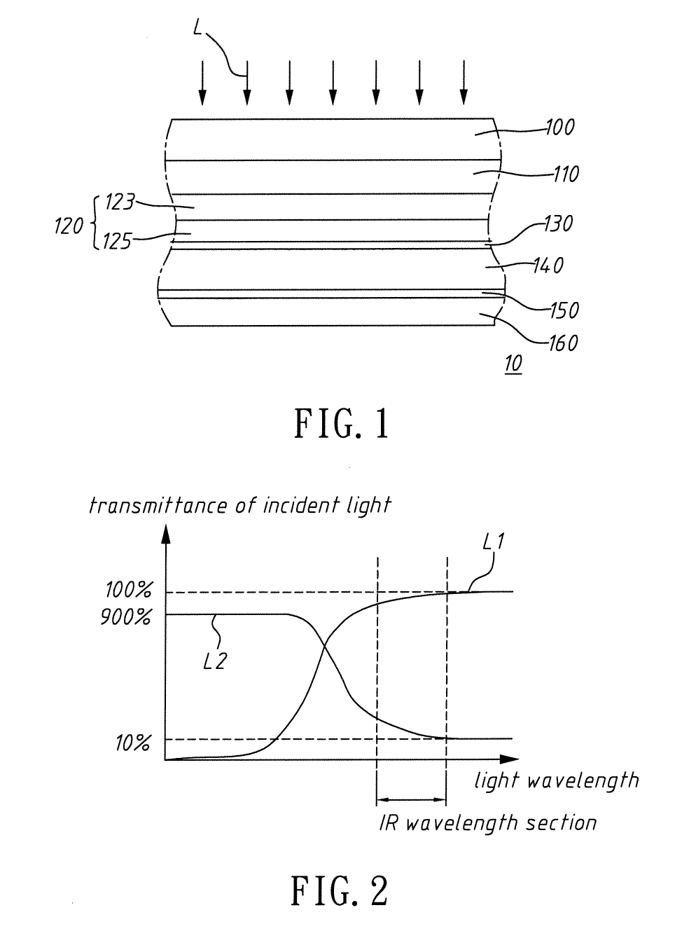

Refer to FIG. 1 for a cross section view of an intelligent thin film solar cell 10 having temperature dependent infrared light transmittance capability according to an embodiment of the present invention. As shown in FIG. 1, thin film solar cell 10 includes a transparent substrate 100, an upper electrode layer 110, a photovoltaic layer 120, a temperature dependent optical layer 130, a lower electrode layer 140, and an ultra-thin conductive layer 150.

The transparent substrate 100 is made of glass, wherein, incident light L enters the thin film solar cell 10 from a side of transparent substrate 100, as shown in FIG. 1. The upper electrode layer 110 is provided on the transparent substrate 100. In the present embodiment, the upper electrode layer 110 is an electrode layer close to the direction of incident light L, and the upper electrode layer 110 is made of transparent conductive oxide, such as, indium tin oxide (ITO), Al doped ZnO (AZO), indium zinc oxide (IZO), ZnO, or other transparent conductive materials.

Refer again to FIG. 1, wherein, the photovoltaic layer 120 is disposed on the upper electrode layer 110. In the present embodiment, when the photovoltaic layer 120 of the thin film solar cell 10 is a single junction structure, then the photovoltaic layer 120 may include an N-type semiconductor layer 123, and a P-type semiconductor layer 125, such that they are disposed in sequence between the upper electrode layer 110 and the lower electrode layer 140. To be more specific, N-type semiconductor layer 123 can be made of amorphous silicon or microcrystalline silicon, and the material doped in N-type semiconductor layer 123 can be selected form VA group elements, such as N, P, As, Sb, or Bi. In addition, P-type semiconductor layer 125 can be made of amorphous silicon or microcrystalline silicon, and the material doped in P-type semiconductor layer 125 can be selected form IIIA group elements, such as B, Al, Ga, In, or, Tl, etc.

The above description is only used as an example for explanation, but the present invention is not limited to this. In other alternative embodiments, the photovoltaic layer 120 of the thin film solar cell 10 can be a double junction or triple junction structure. In other words, the thin film solar cell 10 of the present embodiment can be an amorphous silicon thin film solar cell, a microcrystalline silicon thin film solar cell, a tandem thin film solar cell, or a triple silicon thin film solar cell. It is worth mentioning that, in FIG. 1, the photovoltaic layer 120 may also includes a high temperature intrinsic amorphous silicon layer (not shown), disposed between the N-type semiconductor layer 123 and the P-type semiconductor layer 125, so as to enhance the photoelectric conversion efficiency of the thin film solar cell 10, as shown in FIG. 1.

Refer again to FIG. 1, wherein, the lower electrode layer 140 is disposed on the photovoltaic layer 120. In the present embodiment, the lower electrode layer 140 can be made of transparent conductive oxide, such as Indium Tin Oxide, Aluminum Zinc Oxide, Indium Zinc Oxide, or other transparent conductive materials. In addition, a temperature dependent optical layer 130 is disposed between the photovoltaic layer 120 and the lower electrode layer 140, and the transmittance of infrared light passing through the temperature dependent optical layer can be varied depending on the ambient temperature T. Namely, when the temperature of the temperature dependent optical layer 130 increases to a specific range, the transmittance of the temperature dependent optical layer 130 for infrared light will be reduced. In addition, an ultra-thin conductive layer 150 is disposed on the lower electrode layer 140, to reflect part of infrared light passing through the temperature dependent optical layer 130.

To be more specific, the meaning of the so-called [symbol] intelligent [symbol] thin film solar cell 10 is that, the transmittance of infrared light passing through the thin film solar cell 10 can be varied automatically depending on ambient temperature T. By way of example, when the temperature is excessively high, the transmittance of infrared light passing through the thin film solar cell 10 is reduced, so as to reduce the ratio of infrared light passing through the thin film solar cell 10. As such, in this case, if a greenhouse is made by utilizing the thin film solar cell 10 of the present embodiment, then when the outside temperature is high, the temperature in the greenhouse can be prevented from going too high.

In contrast, when the outside temperature is lower, the ratio of infrared light passing through the thin film solar cell 10 will increase, such that more infrared light in incident light L can pass through. As such, in this case, if a greenhouse is made by utilizing the thin film solar cell 10 of the present embodiment, then the temperature in the greenhouse can easily be increased.

In order to describe the key-point of the present invention, the variation of transmittance of the temperature dependent optical layer 130 along with temperature will be described in detail. Refer to FIG. 2 for a schematic diagram showing the variations of infrared light transmittance of temperature dependent optical layer 130 according to an embodiment of the present invention. Wherein, the horizontal axis indicates wavelength of incident light L, while the vertical axis indicates transmittance of incident light L, with its maximum value of 100% (namely, all the lights can pass through), and with minimum value of 0% (almost all the lights are reflected and blocked). Moreover, the temperature dependent optical layer 130 is made of vanadium dioxide.

In the present embodiment, curve L1 represents the transmittance of the temperature dependent optical layer 130 to the incident light L, when the temperature T of the temperature dependent optical layer 130 is equal to or less than 20° C. (T≦20° C.); and curve L2 represents the transmittance of the temperature dependent optical layer 130 to the incident light L, when the temperature T of the temperature dependent optical layer 130 is equal to or greater than 30° C. (T≧30° C.). From FIG. 2 it can be known that, when the temperature increases to or greater than 30° C. (namely, in a specific range of the temperature dependent optical layer 130, refer to Curve L2), the temperature dependent optical layer 130 will lower its transmittance to the infrared light, as shown as the transmittance in the infrared light IR wavelength section in FIG. 2. In other words, most of the infrared light in incident light L will be reflected and blocked.

In the present embodiment, the transmittance of the temperature dependent optical layer 130 to the infrared light is roughly 10%, that means when the ambient temperature is over 30° C., about 10% of the infrared light in the incident light L can pass through the temperature dependent optical layer 130, and the rest of the infrared will be reflected back to the transparent substrate 100, or be absorbed by the photovoltaic layer 120 and be converted into electrical energy.

In addition, when temperature T drops to below 20° C. (refer to curve L1), the temperature dependent optical layer 130 will increase its transmittance for infrared light, so that most of the infrared light in incident light L can pass through the thin film solar cell 10, therefore, the temperature T of the green house adopting this kind of thin film solar cell will increase. Refer to FIG. 2, at temperature of 20° C., the transmittance of temperature dependent optical layer 130 for the infrared light is about 100%, that means, when temperature is below 20° C., almost all the infrared light in the incident light Loan pass through the temperature dependent optical layer 130, so that the temperature of the green house adopting this kind of the thin film solar cell 10 will increase. As such, in the present embodiment, the transmittance of infrared light of the temperature dependent optical layer 130 is utilized to control the room temperature, so as to reduce the dependence on the air conditioner, hereby saving the electrical energy consumed by the air conditioner.

The transmittance of temperature dependent optical layer 130 for the incident light L, especially for the infrared light depends on the material used for making the temperature dependent optical layer 130, such that when the material utilized is changed, the transmittance curve is FIG. 2 will change accordingly, however, the present invention is not limited to this. In other embodiments, the material of temperature dependent optical layer 130 can be the compound of oxygen and vanadium.

It has to be mentioned that, in the present embodiment, an ultra-thin conductive layer can be used to regulate further the ratio of infrared light passing through the thin film solar cell, so that the lighting and temperature of a building can be controlled through the transmittance of infrared light according to design. Herein, the relations concerning the transmittance/reflectance of the temperature dependent optical layer 130 and the ultra-thin conductive layer 150 for the infrared light are described in detail. In the present embodiment, the thickness of the ultra-thin conductive layer 150 is equal to or greater than 2 nm, and is equal to or less than 20 nm (in the present embodiment, its thickness is about 5 nm), and it is made of transition materials, such as Ni, Ag, or Al, that is capable of reflecting infrared light and enhancing conduction.

In the present embodiment, the thickness and reflectance of the ultra-thin conductive layer 150 to the infrared light can be adjusted according to actual requirements, therefore, the ratio of infrared light transmitted through the thin film solar cell can further be adjusted. Moreover, the conductance of the lower electrode layer 140 can be raised by the ultra-thin conductive layer 150. By way of example, in case that according to actual requirement, it is desired that, when the temperature T is over 30° C., the thin film solar cell 10 is able to reflect 95% of infrared light in the incident light L. In other words, only 5% of infrared light in the incident light L is allowed to be transmitted through the thin film solar cell 10, however, the transmittance of the temperature dependent optical layer 130 for the infrared light at 30° C. is about 10%, therefore, the reflectance of the ultra-thin conductive layer 150 can be designed to be about 5%, so that the transmittance of the thin film solar cell 10 for the infrared light in the incident light L is 5% (10%-5%). Therefore, when temperature T drops to below 20° C., and an ultra-thin conductive layer 150 is provided, then the transmittance of the thin film solar cell 10 for the infrared light in the incident light L is reduced from the original about 100% as shown in FIG. 2 to about 95% (100%-5% infrared light reflectance of the ultra-thin conductive layer 150). In the present embodiment, a transparent substrate 160 can be provided in the thin film solar cell 10, and it is arranged under the ultra-thin conductive layer 150, so as to connect and protect the thin film solar cell 10. In other embodiments, the transparent substrate 160 can also be provided between the lower electrode layer 140 and the ultra-thin conductive layer 150. However, the present invention is not limited to this.

Summing up the above, when sunlight enters a thin film solar cell from a side of a transparent substrate, a temperature dependent optical layer between the photovoltaic layer and the lower electrode layer is able to regulate the transmittance of the thin film solar cell for the infrared light in the sunlight as based on the present temperature. In addition, the ratio of infrared light transmitted through the thin film solar cell can be regulated further through an ultra-thin conductive layer, so that the lighting and temperature of a building can be controlled based on the transmittance of infrared light as designed, hereby reducing utility rate of air conditioners.

Furthermore, in addition to being applicable to a window or a roof of a building in regulating the room temperature, the intelligent thin film solar cell having temperature dependent infrared light transmittance capability of the present invention can also be applicable to a plant or flower cultivating industry requiring much more green light or mixture of blue light and green light, so as to maintain a decent room temperature advantageous for cultivating flowers and plants. In order words, the intelligent thin film solar cell having temperature dependent infrared light transmittance capability of the present invention is able to make great contributions to various Industries.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. An intelligent thin film solar cell having temperature dependent infrared light transmittance capability, comprising:
a transparent substrate;
an upper electrode layer, disposed on said transparent substrate;
a photovoltaic layer, disposed on said upper electrode layer;
a lower electrode layer, disposed on said photovoltaic layer;
a temperature dependent optical layer, disposed between said photovoltaic layer and said lower electrode layer, and its transmittance to infrared light is varied depending on temperature, wherein, when temperature of said temperature dependent optical layer increases to a specific range, its transmittance to said infrared light is reduced; and
an ultra-thin conductive layer, disposed on said lower electrode layer, and reflects said infrared light transmitted through said temperature dependent optical layer.

2. The intelligent thin film solar cell having temperature dependent infrared light transmittance capability as claimed in claim 1, wherein a thickness of said ultra-thin conductive layer is equal to or greater than 2 nm, and is equal to or less than 20 nm.

3. The intelligent thin film solar cell having temperature dependent infrared light transmittance capability as claimed in claim 2, wherein said ultra-thin conductive layer is made of transition metals.

4. The intelligent thin film solar cell having temperature dependent infrared light transmittance capability as claimed in claim 3, wherein said transition metals include Ni, Ag, or Al.

5. The intelligent thin film solar cell having temperature dependent infrared light transmittance capability as claimed in claim 1, wherein said temperature dependent optical layer is made of vanadium oxide or a compound of vanadium and oxygen.

6. The intelligent thin film solar cell having temperature dependent infrared light transmittance capability as claimed in claim 1, wherein said temperature dependent optical layer is doped with Ti, Ag, or Cu.

7. The intelligent thin film solar cell having temperature dependent infrared light transmittance capability as claimed in claim 1, wherein when temperature increases to or over 30° C., transmittance of said temperature dependent optical layer to said infrared light is reduced.

8. The intelligent thin film solar cell having temperature dependent infrared light transmittance capability as claimed in claim 7, wherein when temperature drops to or below 20° C., transmittance of said temperature dependent optical layer to said infrared light is increased.

9. The intelligent thin film solar cell having temperature dependent infrared light transmittance capability as claimed in claim 1, wherein transmittance of said temperature dependent optical layer to said infrared light is reduced along with increase of temperature.

10. The intelligent thin film solar cell having temperature dependent infrared light transmittance capability as claimed in claim 1, wherein said photovoltaic layer includes an N-type semiconductor layer and a P-type semiconductor layer, disposed sequentially between said upper electrode layer and said lower electrode layer.
